(19) United States
(12) Patent Application Publication
(10) Pub. No.: US 2025/0333643 A1
(43) Pub. Date: Oct. 30, 2025

(54) ORGANIC SEMICONDUCTOR FILM AND PREPARATION METHOD THEREOF

(71) Applicant: Shanghai Been Semiconductor Technology Co., Ltd., Shanghai (CN)

(72) Inventor: Xianghua WANG, Hefei, Anhui (CN)

(21) Appl. No.: 18/273,413

(22) PCT Filed: Jan. 11, 2022
(86) PCT No.: PCT/CN2022/071186

§ 371 Date: Dec. 21, 2023

(30) Foreign Application Priority Data
Jan. 20, 2021 (CN) 202110077398.9

(51) Int. Cl. C09K 11/02; B82Y 20/00; B82Y 40/00; C09K 11/66; C30B 19/00; C30B 29/12; C30B 29/16; C30B 29/54; H10K 50/115; H10K 85/60

(52) U.S. Cl. CPC C09K 11/025; C09K 11/665; C30B 19/00; C30B 29/12; C30B 29/16; C30B 29/54; H10K 85/6576; B82Y 20/00; B82Y 40/00; H10K 50/115

(57) ABSTRACT

Provided are an organic semiconductor film and a preparation method thereof. The preparation method includes at least the following steps: preparing an inorganic nanocrystal with a shell structure, performing synchronous ion exchange on an anion and a metal ion in the inorganic nanocrystal with the shell structure to obtain a modified inorganic nanocrystal with a shell structure and a relatively stable structure, dispersing the modified inorganic nanocrystal with the shell structure and a conjugated organic small molecule in an organic solvent to obtain a dispersion, and forming the dispersion into the organic semiconductor film.

### CROSS-REFERENCE TO RELATED APPLICATION

This application is a national stage application of International Patent Application No. PCT/CN2022/071186, filed on Jan. 11, 2022, which claims priority of the Chinese Patent Application No. 2021100773989, filed on Jan. 20, 2021. The disclosure of the two patent applications is incorporated by reference in their entities.

### TECHNICAL FIELD

The present disclosure belongs to the field of semiconductor materials preparation, particularly relates to an organic semiconductor film and a preparation method thereof.

### BACKGROUND

In high-performance semiconductor devices, the semiconductor functional layer is usually required to have a single crystal morphology and have a low defect density at the interface.

Existing semiconductor film growth are mainly performed on two-dimensional plane structure using a gas-phase epitaxial growth technology to form high-quality inorganic semiconductor of single crystal morphology, which ensures a sufficiently low density of interface trap. However, gas-phase epitaxial growth technology requires a high-quality single crystal substrate, and thus cannot be applied to low-cost transparent amorphous substrates such as glass and plastic. Sol-gel methods may produce a special out-of-plane oriented polycrystalline film on an amorphous glass substrate. This indicate the potential of solution processed inorganic films to have the desirable epitaxial growth behavior under specific process conditions, but the corresponding process window is small, and there are many grain boundaries and charge traps inside the film and limits its application in semiconductor devices. In a solution environment, the growth of inorganic materials typically results in polycrystalline morphology, causing unsatisfactory device performance and inferior device stability due to the grain boundaries. However, in the solution environment, the molecules of organic semiconductors assemble via intermolecular van der Waals forces and crystallize into a large single crystal film, thereby suppressing the influence of grain boundaries on device performance. Inorganic nanocrystal electroluminescent devices suppress the influence of interface charge traps on the luminescence performance through a strictly lattice-matching interface or gradient alloy technology. Perovskite nanocrystals also need to improve the fluorescence quantum efficiency through surface passivation using organic ligands. Long-chain organic molecules, such as oleic amine and oleic acid, as quantum dot surface passivation layers, have poor thermal stability and photostability. Heat treatment or light exposure can weaken the surface passivation of perovskite nanocrystals, making it difficult for their electroluminescent devices to break through an external quantum efficiency of 10%. The amorphous layer of surface ligands also hinders the injection and transmission of charge carriers, limiting the brightness of the device. To address this issue, existing technologies improve the electronic transport characteristics of the nanocrystal luminescent layer by selecting short-chain ligands, thereby reducing the distance between quantum dots. From the perspective of photoluminescence performance, these luminescent materials can effectively reduce the surface charge trap density and suppress non-radiative recombination, generally showing longer fluorescence lifetimes and indeed improving the fluorescence quantum efficiency to some extent. However, the reduction of quantum dot spacing will lead to enhanced fluorescence resonance energy transfer (FRET) between neighboring quantum dots, which is also an important reason for the decrease in fluorescence intensity. In addition, although conjugated organic small molecules cause ordered arrangement of molecules through intermolecular 7L-7L interactions, forming organic semiconductor films with out-of-plane and in-plane orientation characteristics, the crystallinity of the film is closely related to the substrate material. Moreover, although the films grown on various substrates have strong (002) and (003) XRD diffraction peaks, higher-order diffraction peaks rarely appear, indicating that the lattice correlation based on the substrate surface structure is limited to a very small area for epitaxial growth.

### SUMMARY

An object of the present disclosure is to provide an organic semiconductor film and a preparation method thereof. The organic semiconductor film is a solution-phase epitaxial organic semiconductor film based on an inorganic nanocrystal template and a fractional matching relationship of lattice parameters. The present disclosure intends to obtain an organic semiconductor film material with excellent optical and carrier transport properties by independently regulating the photoelectric properties and crystal morphology of the organic semiconductor film material.

In order to solve the above technical problems, the present disclosure provides the following technical solutions.

The present disclosure provides a method for preparing an organic semiconductor film, which comprises at least the following steps:
preparing an inorganic nanocrystal with a shell structure, where the inorganic nanocrystal with the shell structure contains at least a metal ion and an anion,
performing synchronous ion exchange on the metal ion and the anion in the inorganic nanocrystal with the shell structure by using an another nanocrystal different from the inorganic nanocrystal with the shell structure to obtain a modified inorganic nanocrystal with a shell structure, where the another nanocrystal contains elements that are different from the anion and the metal ion in the inorganic nanocrystal with the shell structure,
dispersing the modified inorganic nanocrystal with the shell structure and an organic small molecule in an organic solvent to obtain a dispersion, where the organic small molecule has a conjugated molecular structure and the organic small molecule and the modified inorganic nanocrystal satisfy a fractional matching relationship of lattice parameters (also known as domain matching epitaxy relationship), and
forming the dispersion into the organic semiconductor film.

In an embodiment, in the organic semiconductor film, the modified inorganic nanocrystal and the conjugated organic small molecule satisfy a fractional matching relationship of lattice parameters.

In an embodiment, the inorganic nanocrystal with the shell structure are prepared by an in-situ mercaptosiloxane passivation method, a ligand-exchange mercaptosiloxane passivation method, an in-situ aminosiloxane passivation method, or a ligand-exchange aminosiloxane passivation method.

In an embodiment, the dispersion is formed into the organic semiconductor film by inkjet printing, slot-die coating, or screen printing.

In an embodiment, a surface ratio and a crystalline morphology of the organic semiconductor film are controlled by a film thickness of the organic semiconductor film and a volume fraction of the organic small molecule in the organic semiconductor film.

In an embodiment, the surface ratio of the organic semiconductor film is marked as SR, and 0.01<SR<1.

In an embodiment, the ion exchange is performed by a process comprising:

adding the another nanocrystal containing an anion of a different element and a metal ion of a different element into the inorganic nanocrystal with the shell structure, and exchanging the anion in a lattice of the inorganic nanocrystal with that in a lattice of the another nanocrystal, during which the inorganic nanocrystal with the shell structure and the shell structure are relatively stable, and the another nanocrystal gradually dissociate until disappear.

In an embodiment, the another nanocrystal comprises an ion that does not undergo in the ion exchange in a lattice of the inorganic nanocrystal with the shell structure.

In an embodiment, the obtained inorganic nanocrystal is doped in control by changing a type or a molar fraction of an anion and a metal ion that undergo in the ion exchange in the another nanocrystal.

The present disclosure further provides an organic semiconductor film, comprising at least:
a modified inorganic nanocrystal, which has a shell structure, and
an organic small molecule, which has a conjugated small organic molecular structure,
wherein the organic small molecule and the modified inorganic nanocrystal satisfy a fractional matching relationship of lattice parameters.

The present disclosure provides an organic semiconductor film and a preparation method thereof. In the present disclosure, the nanocrystal organic semiconductor composite film, based on solution-phase epitaxy growth achieved by a nanocrystal lattice template, is formed by a technical route of high-dispersion nanocrystal composite film through the van der Waals force self-assembly of the organic small molecule and bulk phase nucleation of quantum dots in the shell structure.

The nanocrystal composite film based on solution-phase epitaxy growth is formed by a technical route of increasing spacing between quantum dots through self-assembly of the organic semiconductor molecule and quantum dots nucleation. In the present disclosure, the solution-phase epitaxy organic semiconductor film based on an inorganic nanocrystal template and a fractional matching relationship of lattice parameters has macroscopic anisotropic carrier transport properties and a low trap density, which avoids the contradiction between the optical properties and electrical properties of the film in principle. In the present disclosure, quasi-continuous and efficient regulation of properties and morphology is achieved by ion exchange between the inorganic nanocrystals. The organic semiconductor film prepared in the present disclosure has novel or more excellent photoelectric properties, such as ultra-fast radiation recombination, higher optical absorption coefficient and fluorescence quantum efficiency. The organic semiconductor film and the inorganic nanocrystal with a shell structure prepared according to the present disclosure have high stability, and the materials thereof have significantly improved solution processing properties.

It should be noted that not all of the advantages described above need to be present in every embodiment of the present disclosure.

### BRIEF DESCRIPTION OF THE DRAWINGS

In order to clearly illustrate the technical solutions according to embodiments of the present disclosure, the figures used in the description of the embodiments are briefly described below. It is clear that the figures described below are only some embodiments of the present disclosure, and ordinary skilled in the art can obtain other figures based on these figures without creative work.

FIG. 1 shows a flow chart of a method for preparing an organic semiconductor film according to the present disclosure.

FIG. 2 shows a three-dimensional mesh diagram of a surface ratio of an organic semiconductor film of a cubic nanocrystal with a side length of 13 nm.

FIG. 3 shows a contour map of a surface ratio of an organic semiconductor film of a cubic nanocrystal with a side length of 9 nm.

FIG. 4 shows schematic diagrams of the interfaces that each satisfy a fractional matching relationship of lattice parameters and a strict lattice matching relationship in right panel and left panel.

FIG. 5 shows an X-ray diffraction (XRD) pattern of in-situ mercapto-nanocrystal (InMP-CsPbBr₃) nanocrystal film prepared by drop-coating on a glass substrate.

FIG. 6 shows an XRD pattern of mercapto-exchanged nanocrystal (ExMP-CsPbBr₃) nanocrystal powder.

FIG. 7 shows a fluorescence spectrum of ExMP-CsPbBr₃ nanocrystal after exchanged with different volume percentages of 3-mercaptopropyl trimethoxysilane (MPTMS) ligand.

FIG. 8 shows an absorption spectrum of ExMP-CsPbBr₃ nanocrystal prepared by a ligand exchange method.

FIG. 9 shows a fluorescence quantum yield (PLQY) of ExMP-CsPbBr₃ nanocrystal after exchanged with different volume percentages of MPTMS ligand.

FIG. 10 shows a PLQY of mixed-color nanocrystals with different colors.

FIG. 11 shows a fluorescence quantum efficiency (PLQE) of CsPbBr₃/C₈-BTBT nanocrystal composite film measured with different excitation wavelengths.

FIG. 12 shows a transmission electron microscope (TEM) image of ExAP-CsPbBr₃ nanocrystal.

FIG. 13 shows a size distribution statistical graph of ExAP-CsPbBr₃ nanocrystal.

FIG. 14 shows a fluorescence intensity change of ExAP-CsPbBr₃ nanocrystal and a control sample in ethanol solvent environment.

FIG. 15 shows a fluorescence quantum efficiency (365 nm excitation) of nanocrystal films with different structures and small molecule composite films thereof.

FIG. 16 shows an XRD pattern of an InMP-CsPbBr₃/C₈-BTBT and CsPbBr₃/C₈-BTBT nanocrystal composite film.

FIG. 17 shows an overlap of C₈-BTBT (005) and (007) XRD pattern of the organic semiconductor film according to an embodiment of the present disclosure and InMP-CsPbBr₃ diffraction.

### DETAILED DESCRIPTION OF THE EMBODIMENTS

The technical solutions of embodiments of the present disclosure will be described below clearly and completely in conjunction with the accompanying drawings according to the embodiments of the present disclosure. Obviously, the described embodiments are only a part of the embodiments of the present disclosure, and not all embodiments. Based on the embodiments of the present disclosure, all other embodiments obtained by those ordinary skilled in the art without creative work shall fall within the scope of the present disclosure.

An application of a nanocrystal epitaxial film in devices often requires well-defined lattice parameters or interplanar spacing, which requires that within a given process window, the nanocrystal used as a template material can design the properties of the nanocrystal and has controllable lattice parameters or interplanar spacing (i.e., crystal morphology). For conventional materials, the properties are closely related to morphology, and different properties, such as optical properties and electrical properties, are often contradictory. In the present disclosure, the morphology and properties of the film could be regulated independently, and the contradiction between the optical properties and electrical properties of the film material could be solved.

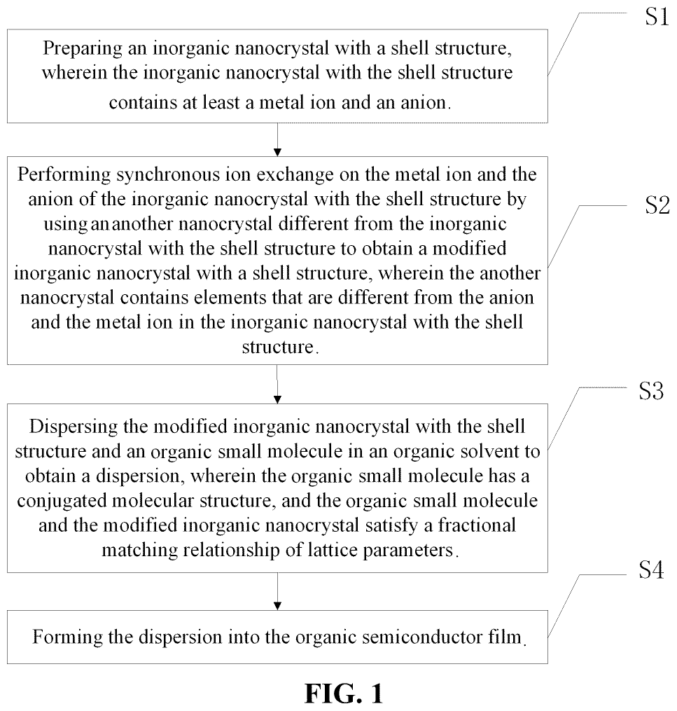

Referring to FIG. 1, the present disclosure provides a method for preparing an organic semiconductor film, which comprises at least the following steps:

S1. preparing an inorganic nanocrystal with a shell structure, wherein the inorganic nanocrystal with the shell structure contains at least a metal ion and an anion,

S2. performing synchronous ion-exchange on the metal ion and the anion of the inorganic nanocrystal with the shell structure by using an another nanocrystal different from the inorganic nanocrystal with the shell structure to obtain a modified inorganic nanocrystal with a shell structure, wherein the another nanocrystal contains elements that are different from the anion and metal ion in the inorganic nanocrystal with the shell structure;

S3. dispersing the modified inorganic nanocrystal with the shell structure and an organic small molecule in an organic solvent to obtain a dispersion, wherein the organic small molecule has a conjugated molecular structure, and the organic small molecule and the modified inorganic nanocrystal satisfy a fractional matching relationship of lattice parameters, and

S4. forming the dispersion into the organic semiconductor film.

Referring to FIG. 1, in step S1, the inorganic nanocrystal with the shell structure may be prepared by introducing a siloxane ligand in-situ during the preparation of nanocrystal or performing siloxane ligand exchange in a prepared nanocrystal dispersion. In some embodiments, the inorganic nanocrystal can be an inorganic perovskite quantum dot. Specifically, in a specific embodiment, the inorganic perovskite quantum dot can be a cesium lead halide perovskite quantum dot. In a specific embodiment, the shell structure can be amorphous or partially crystalline morphology, such as an amorphous silicon oxide shell structure. Specifically, the inorganic nanocrystal with an amorphous or partially crystalline shell structure can be prepared by an in-situ mercaptosiloxane passivation method or a ligand exchange mercaptosiloxane passivation method; or, the inorganic nanocrystal with the shell structure can be prepared by an in-situ aminosiloxane passivation method or a ligand exchange aminosiloxane passivation method.

Taking a preparation of the cesium lead halide perovskite quantum dot as an example in this embodiment, the in-situ mercaptosilane passivation method for preparing the inorganic nanocrystal includes at least the following steps: first, preparing a cesium precursor solution and a lead halide precursor solution, separately; then, mixing the cesium precursor solution with a mercaptosilane, injecting the resulting mixture into the lead halide precursor solution through a thermal injection method for reaction, naturally aging a siloxane passivated nanocrystal obtained from the reaction in an air environment to obtain a cesium lead halide perovskite quantum dot with a silicon oxide shell structure on a surface thereof. Specifically, the method comprises: under a protection of an inert gas, adding cesium carbonate, octadecene, and oleic acid into a three-neck flask and heating to, for example, 120° C. and holding for, for example, 1 hour, and then, heating to, for example, 150° C. and holding until the cesium carbonate is completely dissolved to obtain a cesium precursor solution; under a protection of an inert gas, adding octadecene and lead halide to a three-neck flask, heating to, for example, 120° C., and holding for, for example, 1 hour and then, injecting oleylamine and oleic acid thereto and holding until the lead halide is completely dissolved to obtain a lead halide precursor solution; heating the lead halide precursor solution to, for example, 160-165° C. within, for example, 10 minutes, mixing the cesium precursor solution with mercaptosilane, and preheating to, for example, 100-120° C., and then, quickly injecting a resulting heated mixture into the lead halide precursor solution that has been heated, reacting for, for example, 3-7 seconds, quickly placing a resulting reaction mixture to an ice water bath for cooling, thus stopping the reaction; and purifying an obtained product to obtain a cesium lead halide perovskite quantum dot with a passivation layer on a surface thereof. In some embodiments, amounts of raw materials greatly affect the morphology and properties of the product. Through experiments, optimal ratios of raw materials determined in this application are as follows: a ratio of cesium carbonate to octadecene to oleic acid is, for example, 0.3-0.4 g: 16 mL: 1 mL; a ratio of octadecene to lead halide to oleylamine to oleic acid is, for example, 5-10 mL: 0.05-0.14 g: 0.5-1 mL: 1-1.5 mL; a ratio of the cesium precursor solution to the mercaptosilane to lead halide precursor solution is, for example, 1-1.2 mL: 0.8 mL: 6.5-12.5 mL. In some embodiments, the mercaptosilane is 3-mercaptopropyltrimethoxysilane, which is a specific molecular structure of mercaptosiloxane. Different molecular structures of siloxane also greatly affect the properties of the product. For example, when 3-aminopropyltrimethoxysilane is used for preparation according to the same method, the fluorescence performance of the obtained cesium lead halide perovskite quantum dot rapidly decreases during the purification process and disappears after 12 hours. However, by adjusting the specific method of in-situ introduction and using a surface passivation effect of an auxiliary reagent such as ZnBr₂, a high-performance nanocrystal fluorescence material can still be prepared.

Referring to FIG. 1, taking the preparation of a cesium lead halide perovskite quantum dot as an example in this embodiment, the ligand exchange mercaptosiloxane passivation method for preparing the inorganic nanocrystal includes at least the following steps: adding 3-mercaptopropyltrimethoxysilane into a dispersion of a perovskite quantum dot in non-polar solvent, where the dispersion is prepared by a thermal injection with oleylamine and oleic acid as surface ligands, and reacting under stirring, such that 3-mercaptopropyltrimethoxysilane as a new surface ligand replaces an original surface ligand, obtaining an inorganic nanocrystal with an amorphous or partially crystalline shell structure. In a specific embodiment, the mercapto group of 3-mercaptopropyltrimethoxysilane forms a stable Pb—S covalent bond with lead atoms on the surface of the perovskite quantum dot, thus improving the fluorescence quantum efficiency and solution processing properties of the perovskite quantum dot. A mass ratio of the perovskite quantum dot to 3-mercaptopropyltrimethoxysilane is, for example, 1.2-2:1. In some embodiments, the reaction under stirring is performed at ambient temperature for, for example, 12 hours.

Referring to FIG. 1, taking the preparation of a cesium lead halide perovskite quantum dot as an example, the ligand exchange amino siloxane passivation method for preparing an inorganic nanocrystal includes at least the following steps: preparing a dispersion of a perovskite quantum dot in a non-polar solvent by thermal injection with oleylamine and oleic acid as surface ligands, where the dispersion has a quantum dot concentration of about 10 mg/mL; mixing oleyl acid and the dispersion of the quantum dot at a volume ratio of 5%, then adding 3-aminopropyl trimethoxysilane at a volume percentage of 1.5% thereto, and stirring at ambient temperature for 5-10 minutes, such that 3-aminopropyl trimethoxysilane replaces an original surface ligand, to obtain a quantum dot mother liquor; mixing the quantum dot mother liquor with ethyl acetate, and washing a resulting mixture by centrifugation to obtain a precipitate, and dispersing the precipitate in a solvent to obtain a purified quantum dot dispersion. In a specific embodiment, halogen atoms on the surface of the perovskite quantum dot combine with an amino group of the aminosiloxane molecule through hydrogen bonds, ultimately forming a silica shell, and the fluorescent quantum efficiency of the perovskite quantum dot is improved to 98%, with significantly improved tolerance to polar solvents. The method according to this embodiment is easy to operate, and has a short ligand exchange reaction time.

Referring to FIG. 1, in step S2, synchronous ion exchange is performed on the anion and metal ion of the inorganic nanocrystal with the shell structure to obtain a modified inorganic nanocrystal with a shell structure. In some embodiments, the anion is a halogen atom. In a specific embodiment, the ion exchange is performed by a process including: adding an another nanocrystal containing an anion of a different element and a metal ion of a different element to the inorganic nanocrystal with the shell structure, such that the anion in a lattice of the inorganic nanocrystal with the shell structure exchange position with the anion in a lattice of the another nanocrystal. During this process, the inorganic nanocrystal with the shell structure and the shell structure thereof are relatively stable, while the another nanocrystal gradually dissociate until disappear. The another nanocrystal also contains an ion that is not exchanged in a lattice of the inorganic nanocrystal with the shell structure. By changing a type or a molar fraction of the anion and metal ion exchanged in the another nanocrystal, the inorganic nanocrystal with the shell structure can be doped in control. The core-shell structure nanocrystal with a partially crystalline silica shell obtained by controlled doping have independently controllable properties, including optical band gap, absorption coefficient, exciton binding energy, and electronic band structure of heterojunctions. The silica shell structure prepared according to the present disclosure is helpful in modulating the optical properties of the nanocrystal through ion exchange. This is because the inorganic nanocrystal with a silica shell structure has a lower crystallinity than that of the inorganic nanocrystal without the shell structure, and halogen atom in the inorganic nanocrystal with the silica shell structure are more prone to ion exchange, making it easier to modulate the optical properties of the nanocrystal.

Referring to FIG. 1, in step S3, the modified inorganic nanocrystal with the shell structure and an organic small molecule are dispersed in an organic solvent to obtain a dispersion.

Specifically, the inorganic nanocrystal with the shell structure, such as an inorganic perovskite quantum dot, and a conjugated organic small molecule are dispersed in an organic solvent, where the organic small molecule has a conjugated molecular structure, and the organic small molecule and the modified inorganic nanocrystal satisfy a fractional matching relationship of lattice parameters. In some embodiments, the organic solvent can be, for example, heptane, p-xylene, or tetrahydronaphthalene, or a mixed organic solvent thereof. In a specific embodiment, the organic small molecule is, for example, 2,7-dioctyl[1]benzothieno[3,2-B][1]benzothiophene (C8-BTBT), and the organic solvent is a mixture of heptane and tetrahydronaphthalene.

Referring to FIG. 1, in step S4, the dispersion is formed into the organic semiconductor film. Specifically, in some embodiments, the organic semiconductor film is formed by processes such as dip-coating, inkjet printing, slot-die coating, or spin-coating. In a specific embodiment, a cesium lead halide perovskite quantum dot with a shell structure is mixed with C8-BTBT to obtain a mixed ink, and an organic semiconductor film is prepared by spin-coating. In another embodiment, solution-based processes such as inkjet printing and screen printing can be used to prepare the organic semiconductor film. A surface ratio SR and a crystalline morphology of the film are controlled by a thickness of the organic semiconductor film and the volume fraction of the small molecule in the film, where the surface ratio of a surface area of the shell structure to a surface area of the organic semiconductor film is marked as SR, and 0.01<SR<1.

Referring to FIG. 1, the inorganic perovskite quantum dot with the shell structure in the organic semiconductor film has a rigid perovskite structure relative to the conjugated organic micromolecule, and the conjugated organic micromolecule has a plastic lattice structure relative to the inorganic perovskite quantum dot, and the inorganic perovskite quantum dot and the conjugated organic micromolecule have a similar lattice size in a-axis and b-axis directions, allowing the inorganic perovskite quantum dots to undergo epitaxial orientation through the self-assembly of the conjugated organic small molecule in a solution environment. Meanwhile, the inorganic perovskite quantum dot and the conjugated organic small molecule form type I heterojunction, which enhances the absorption efficiency of high-energy photons and the transmission and injection efficiency of photogenerated carriers, while suppressing non-radiative recombination of carriers, thereby increasing the luminescence intensity of the inorganic perovskite quantum dot. In some embodiments, a mass ratio of the inorganic perovskite quantum dot with the shell structure to the conjugated organic small molecule in the dispersion can be 1:4 to 1:2. By XRD, it could be determined that in the above range, the organic small molecule has a highly oriented crystallization, and the quantum dot and the organic small molecule form an organic semiconductor film, thus allowing for epitaxial orientation of the quantum dot. In some embodiments, a concentration of the inorganic perovskite quantum dot in the dispersion is, for example, 1-20 mg/mL. The non-radiative transition of the excited state carriers is inhibited by the composite of the inorganic perovskite quantum dot and the conjugated organic small molecule in the organic semiconductor film, thus extended the lifetime of the carriers. Oriented epitaxial effect resulting from the lattice interaction between the inorganic perovskite quantum dot and the conjugated organic small molecule reduces the injection barrier for carriers from the organic matrix material to the inorganic quantum dot material. The type I heterojunction formed by the inorganic perovskite quantum dot and the conjugated organic small molecule is conducive to the formation of exciton-bound state of carriers in the low dielectric constant conjugated organic small molecule material, and the carriers are injected into the inorganic perovskite quantum dot material in a balanced manner, thereby improving the quantum efficiency of luminescence.

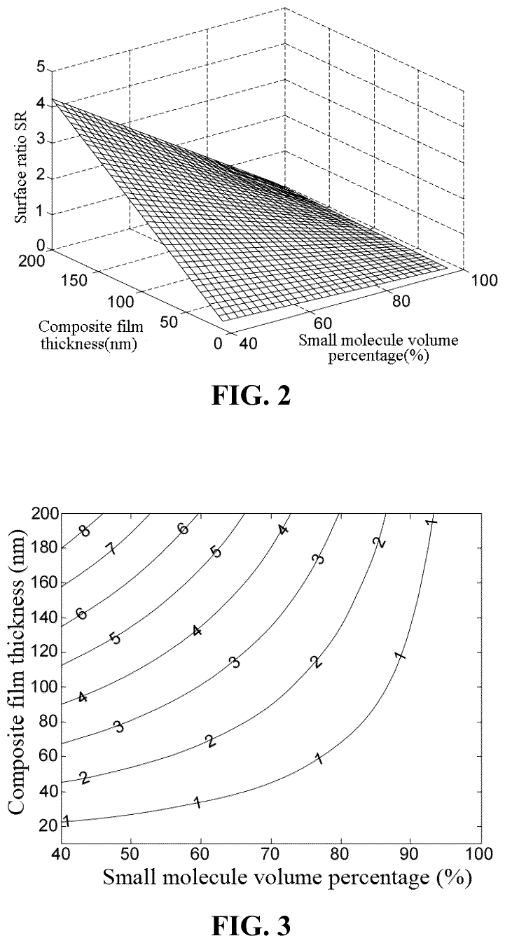

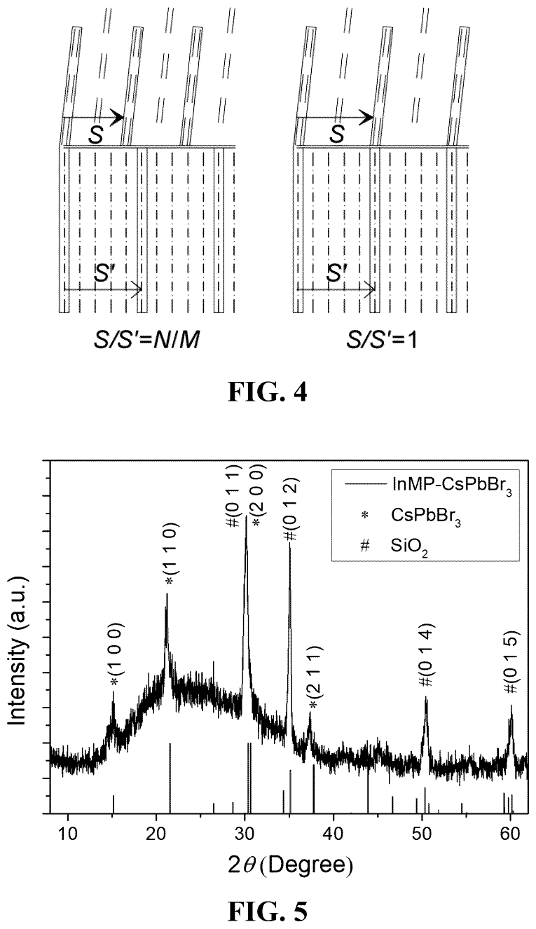

Referring to FIGS. 2-4, by forming a shell structure in the organic semiconductor film, the distance between inorganic perovskite quantum dots is increased, and an organic semiconductor film based on solution-phase epitaxy growth is formed by the self-assembly of the organic semiconductor molecule and the nucleation of the quantum dot. Due to the relatively low symmetry and relatively high plasticity of the host material, the fractional matching relationship of lattices or fractional matching relationship of reciprocal lattices can be easily satisfied between the inorganic nanocrystals, i.e., the inorganic perovskite quantum dot, and the organic small molecule semiconductor. This is based on the continuity of the lattice parameters formed by the epitaxial growth of the inorganic nanocrystal template.

Referring to FIGS. 2-4, specifically, due to the relatively low symmetry and relatively high plasticity of the host material, by XRD 2θ scan, it is easy to observe the multi-level crystal plane diffra6ction (00l) of the organic small molecule semiconductor with l>3, and the peak is located at 2θ₂, and overlaps with the main diffraction peak 2θ₁ of the inorganic nanocrystal, and the crystal plane indexes are in integer ratio relationship, that is, fractional matching relationship. According to overlapping degree of peaks, the lattice mismatch δ is calculated, and the requirement of solution-phase epitaxy is usually satisfied when δ<1%. This is an important technical route for developing solution semiconductor process.

$$δ = \frac{sin {θ}_{2} - sin {θ}_{1}}{sin {θ}_{1}}$$

The above is the main step of judging lattice matching of solution epitaxy based on the crystal phase matching relationship according to the out-of-plane direction. Similarly, the in-plane lattice relationship between the nanocrystal and the organic epitaxial lattice can be analyzed by XRD φ scan, transmission electron microscopy, and selected area electron diffraction. In addition, the lattice matching of solution epitaxy can be judged by analyzing the changes in optical and electrical properties of the composite film.

Referring to FIGS. 2 to 4, the fractional matching relationship is as follows: the organic small molecule and the inorganic nanocrystal compose a guest-host composite structure, where the organic small molecule acts as the host of the film and comprises the major fraction in volume. The lattice basic vectors of the organic semiconductor are defined as a, b, and c, and the lattice basic vectors of the inorganic nanocrystal are defined as a′, b′, and c′. The lattice of the organic semiconductor in the film has a significant out-of-plane orientation characteristic of the c-axis, where the plane formed by the lattice basic vectors a and b is parallel to the surface of the film. The lattice of the organic semiconductor matches the lattice of the nanocrystal at a fractional matching relationship of lattice parameters, where there is at least one lattice basic vector S′_{u′v′w′}=u′a′+v′b′+w′c′ with a crystal direction index [u′v′w′] in the lattice of the inorganic nanocrystal, which is parallel to the direction of a lattice basic vector of S_{uvw}=ua+vb+wc with a crystal direction index [u v w] in the lattice of the organic semiconductor, and the magnitude ratio of S′_{u′v′w′} to S_{uvw}, is N/M, where u, v, w, u′, v′, w′ each are natural numbers less than 10, N and M are positive integers less than 10, and u+v+w<10, u′+v′+w′<10, N+M<10. Similarly, the fractional matching relationship is defined for the reciprocal lattice: the reciprocal lattice vectors G′_{h′k′l′} and Gₕₖₗ, relating to the guest and the host lattice respectively in reciprocal space, are parallel in direction, and a magnitude ratio of G′_{h′k′l′} to Gₕₖₗ is in a fractional ratio. The specific interface interaction between the host and guest during the film formation process is as follows: the inorganic nanocrystal undergo preferential orientation under the influence of the organic semiconductor molecule, and the inorganic nanocrystal regulate the crystal growth process and lattice stress of the organic semiconductor through a fractional epitaxy growth relationship. The resulting organic semiconductor has an anomalous lattice constant compared to a single-component film, that is, the organic semiconductor is different from pure organic semiconductor film, with deviations usually greater than 5%. The preferential orientation of the above nanocrystal and lattice constants of the organic small molecule can be determined by XRD. According to the fractional matching relationship of lattice parameters of the present disclosure, the organic molecules are bound through van der Waals forces to form crystal morphology of a long-range ordering, which compose the host of the film, and relieves the strict requirements on substrate lattice parameters for epitaxial growth of the semiconductor in traditional concepts. The use of the nanocrystal/organic small molecule epitaxial growth mechanism with a fractional matching relationship effectively expands the design space of film materials.

Referring to FIGS. 1 to 4, the silica shell structure prepared according to the present disclosure using a solution method are polymorphic and highly stable in air. On one hand, the silica shell enhances the stability and solvent dispersion of the nanocrystal, enabling the regulation of nanocrystal properties based on controlled ion doping. On the other hand, it is easy to form a bridge transition effect between the nanocrystal nucleus and the lattice of the organic molecules, enabling more coherent epitaxial growth. By using the same material system, materials with high-precision design requirements can be achieved by continuously regulating parameters of the materials such as density, dielectric constant, conductivity, and fluorescence quantum efficiency, based on lattice stress and spatial size effects. In particular, under a condition that an inorganic nanocrystal is used as an epitaxial template, the nanocrystal and the organic semiconductor molecule can be dissolved in an organic solvent together, forming a composite semiconductor film by solution-phase epitaxy growth. Such semiconductor materials have broad application prospects in optoelectronic and microelectronic devices and exhibit excellent properties that single-component materials cannot achieve. In terms of processing, a substrate material for gas-phase epitaxial growth expands the range of substrate lattice parameters.

Referring to FIGS. 1 to 4, in the present disclosure, the solution-phase epitaxy organic semiconductor film based on a template of the inorganic nanocrystal with a shell structure and a fractional matching relationship of lattice parameters has macroscopic anisotropic carrier transport properties and a low trap density, thus avoiding the contradiction between the optical and electrical properties of the film in principle, and achieving quasi-continuous and efficient regulation of properties and morphology based on controlled doping of the inorganic nanocrystal. The organic semiconductor film prepared according to the present disclosure can exhibit new or better optoelectronic properties, such as ultrafast radiation recombination, higher absorption coefficient and fluorescence quantum efficiency. The organic semiconductor film and the shell-structured nanocrystal prepared according to the present disclosure have higher stability, and the material's solution processing properties are significantly improved. The optical or electrical properties of the organic semiconductor film prepared according to the present disclosure are significantly different from those of pure inorganic nanocrystal films and guest-host organic semiconductor films without solution epitaxy.

Referring to FIGS. 1 to 4, the present disclosure further provides an organic semiconductor film, which comprises at least: a modified inorganic nanocrystal, and an organic small molecule. The modified inorganic nanocrystal has a shell structure, the organic small molecule has a conjugated molecular structure, and the organic small molecule and the modified inorganic nanocrystal satisfy a fractional matching relationship of lattice parameters. The preparation method of the organic semiconductor film are as described before, and will not be repeated.

Referring to FIGS. 1 to 14, specifically, the present disclosure will be described in detail in conjunction with the following examples.

### Example 1

Referring to FIG. 5, an InMP-CsPbBr₃ was prepared by an in-situ mercaptosilane passivation method. Specifically, MPTMS was added as a ligand into a precursor solution when using a thermal injection method to prepare a CsPbBr₃ nanocrystal. A nanocrystal film was prepared on a glass substrate by a drop-coating method, and an XRD pattern of the nanocrystal film obtained from a 20 scan is shown in FIG. 5. The XRD pattern shows that the cubic lattice of CsPbBr₃ and the hexagonal lattice of silicon oxide have lattice coherence, which specifically has the following characteristics: (1) the interplanar spacing between the (200) planes of the cubic phase, d₂₀₀, is close to that of the d₀₁₁ of the hexagonal phase, corresponding to 20 diffraction peaks at about 30.6° and about 30.4°, respectively; (2) with reference to the cylinder height of the PDF card, the (200) diffraction peak of the cubic phase CsPbBr₃ is significantly enhanced relative to the (211) diffraction peak, indicating a preferred out-of-plane orientation of a-axis of the cubic phase; (3) the diffraction peak of the hexagonal phase silicon oxide mainly comes from (01l) crystal plane diffraction of the glass substrate, where l=1, 2, 4, 5, which matches with silicon oxide-PDF #97-015-5243. The back diffraction from 15° to 350 is from amorphous silicon oxide, including the silicon oxide shell layer of the nanocrystal. This example indicates that the CsPbBr₃ nanocrystal and the glass substrate have a good lattice matching relationship (6<0.01%). Therefore, it can be inferred that the nanocrystal and partially crystallized silicon oxide shell structure have similar lattice parameters, forming a high-quality heterojunction interface. The InMP-CsPbBr₃ nanocrystal with a shell structure obtained in this example can be used as a high-performance green fluorescent material with a PLQY of up to 99% and good stability.

### Example 2

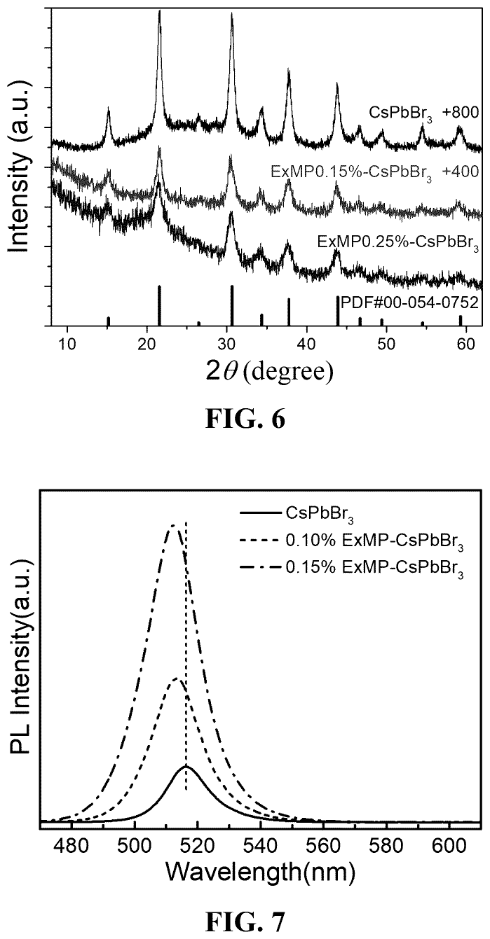

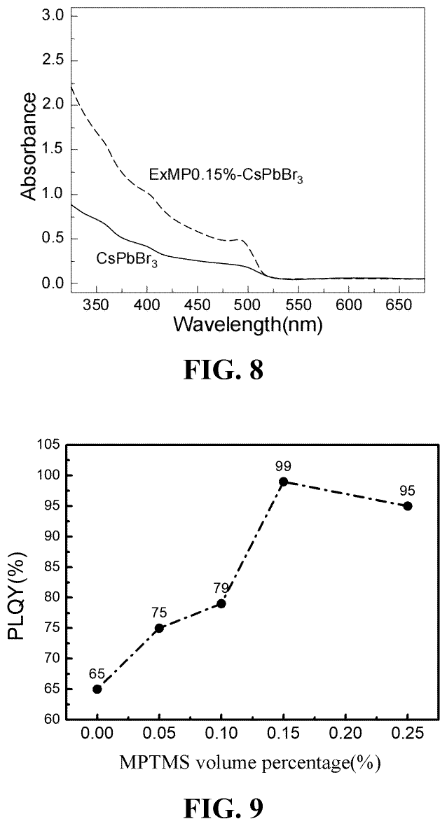

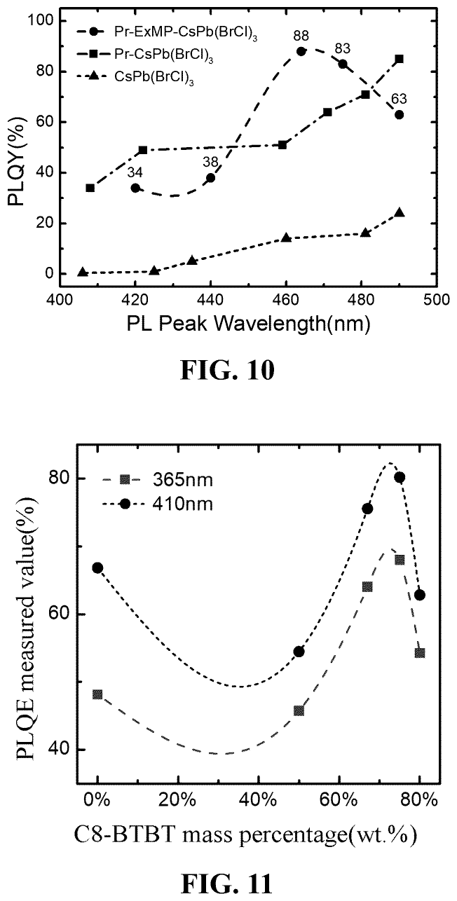

Referring to FIGS. 6 to 10, different from Example 1, in the present example, a mercapto-exchanged nanocrystal (ExMP-CsPbBr₃) passivated by mercaptosilane was prepared by ligand exchange, and an XRD pattern of the nanaocrystal powder with a shell structure is shown in FIG. 6. In this method, MPTMS was not added into a precursor solution when using a thermal injection method to prepare a CsPbBr₃ nanocrystal. A CsPbBr₃ nanocrystal dispersion in heptane was mixed with MPTMS at a certain volume ratio at ambient temperature and stirred for 12 hours to obtain the ExMP-CsPbBr₃ nanocrystal. Compared with a control sample without ligand exchange, the (200) diffraction peak of the cubic phase CsPbBr₃ has a slight peak shift towards a direction of small angle, and the crystallinity is decreased to some extent, which results from a stress applied by the silicon oxide shell layer on the cubic lattice of the perovskite. Referring to FIG. 7, the peak of the steady-state fluorescence spectrum has a slight blue shift (<5 nm). FIGS. 8 and 9 show a significant increase in the absorption coefficient and fluorescence quantum efficiency. By using the existing anion exchanged or metal ion dopped mixed anion perovskite nanocrystals, nanocrystals with different emission colors can be obtained, but the PLQY in the blue light band (<470 nm) is still lower than 60%. Therefore, blue light nanocrystals are a bottleneck for technology applications. Through ion exchange, a CsPbBr₃ nanocrystal was prepared by a thermal injection method, and a CsMCl₃ or other stoichiometric nanocrystal intermediates such as Cs₃MCl₆ were prepared by the thermal injection method, where M represents a metal ion. In this example, the intermediate nanocrystal used was specifically Cs₃PrCl₆, which was mixed with CsPbBr₃ nanocrystal to obtain nanocrystal fluorescent materials with different bandgaps, and the corresponding fluorescence spectra show a significant blue shift. Compared with the ion exchange technology without a shell structure, as shown in FIG. 10, a wavelength shift corresponding to the maximum PLQY shifts to the blue light band (464 nm). This example illustrates that the silicon oxide shell layer is benefit to regulating the optical properties of nanocrystals through ion exchange.

### Example 3

Referring to FIG. 11, in order to investigate the efficiency of non-equilibrium carriers transferring from organic small molecule lattices to nanocrystals in a composite film, two different energy excitation wavelengths were used to measure the fluorescence quantum efficiency, marked as PLQE, which is distinguished from the PLQY of a nanocrystal dispersion. As shown in FIG. 11, low-energy photons, such as 410 nm photons, are only absorbed by nanocrystals, so low-energy photons directly excite nanocrystals, and the measured PLQE is high. When high-energy photons, such as 365 nm photons, are used to excite, the energy is mainly absorbed by the small molecule lattice, and the non-equilibrium carriers generated by light absorption need to be transferred and injected into the nanocrystals to contribute to light radiation. Generally, when the mass percentage of the organic small molecule is greater than, for example, 60% (corresponding volume fraction is, for example, greater than 85%), the PLQE excited by high-energy and low-energy photon is significantly increased, which is attributed to the significant improvement of long-range order of small molecule lattices.

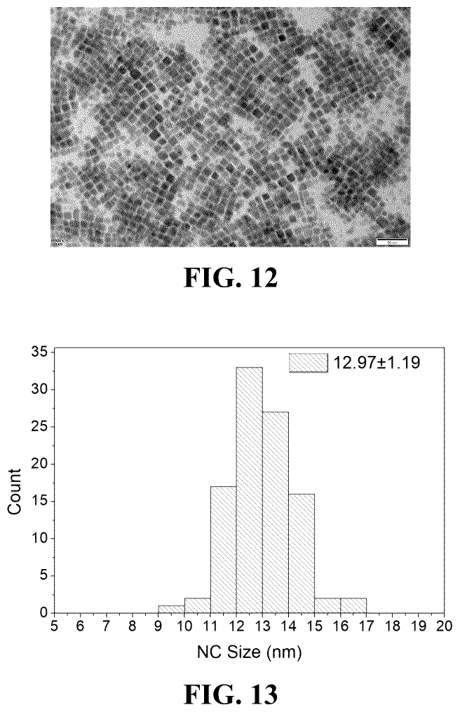

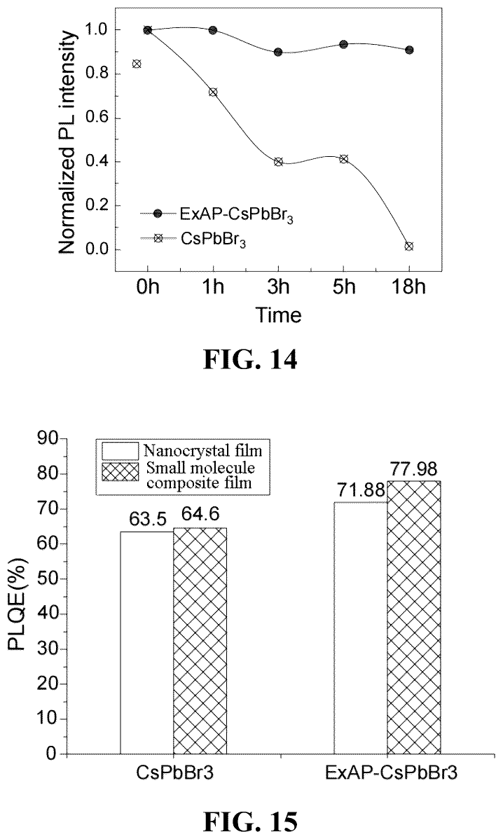

Referring to FIG. 12, different from Examples 1 and 2, in this example, an ExAP-CsPbBr₃ nanocrystal passivated by amino-silane was prepared by ligand exchange. The TEM morphology (see FIG. 12) and size distribution (see FIG. 13) of the nanocrystal are relatively uniform. After adding ethanol at a volume ratio of 35%, the fluorescence intensity of the ExAP-CsPbBr₃ nanocrystal varies with time as shown in FIG. 14, and the fluorescence intensity remains above 90% of the initial value within 18 hours.

Referring to FIG. 15, different from Examples 1 and 2, an ExAP-CsPbBr₃ nanocrystal passivated by amino-silane was prepared by ligand exchange. The nanocrystal was further mixed with C8-BTBT to obtain a mixed ink, and a composite film was prepared on a single crystal silicon wafer by a spin-coating method. A volume fraction of C8-BTBT in the film is about 80%, and PLQE of the film was measured. By using ultraviolet light of, for example, 365 nm, the PLQE of the film can reach 77%, which is significantly higher than that of the nanocrystal epitaxial composite film without a silicon oxide shell layer shown in FIG. 15. Similarly, high-energy excitation light, for example 365 nm excitation light, is primarily absorbed by the small molecule host material in the composite film, but the small molecule host material C8-BTBT has no fluorescence performance. The improvement of the fluorescence performance of the composite film depends on the efficient transfer and injection of photo-generated carriers into the perovskite nanocrystals. Therefore, this example illustrates that the film prepared by a solution method process using a mixed ink obtained by mixing a nanocrystal with a silicon oxide shell layer and a small molecule semiconductor material has higher nanocrystal fluorescence performance and carrier transport capability.

### Example 4

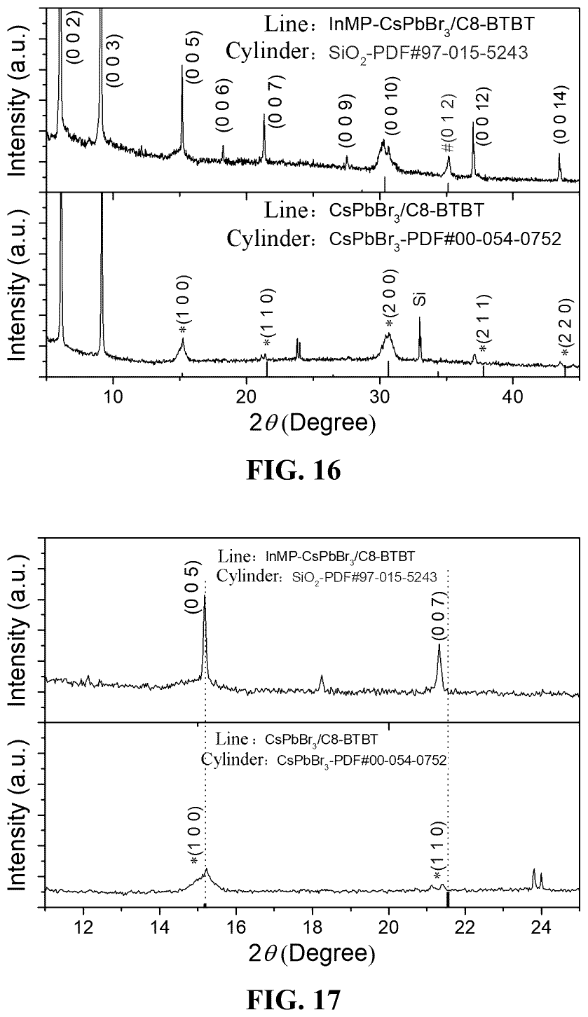

Referring to FIGS. 16 and 17, the InMP-CsPbBr₃ nanocrystal prepared according to Example 1 were mixed with C8-BTBT to form a mixed ink, and an organic semiconductor film was prepared on a glass substrate by a spin-coating method, where a volume fraction of C8-BTBT in the film is about 80%. An XRD pattern of the composite film was measured by 20 scan. Compared with the nanocrystal composite film without a silicon oxide shell layer, more C8-BTBT (00l) multi-level diffraction peaks appear in the XRD pattern of the composite film with a silicon oxide shell layer, as shown in FIG. 16, indicating that the nanaocrystal with a silicon oxide shell layer makes it easier to obtain large-area correlated long-range ordered films. FIG. 17 shows the overlaod of the peak positions of C8-BTBT (005) and (007) with the diffraction peaks of InMP-CsPbBr₃ and its PDF card peak positions. Obviously, the (005) peak of C8-BTBT highly overlaps with the (110) diffraction peak of CsPbBr₃, which is the main mechanism of epitaxial growth, and the (001) out-of-plane orientation characteristic of the small molecule in the InMP-CsPbBr₃/C8-BTBT composite film is stronger than that of the control group CsPbBr₃/C8-BTBT composite film. According to the correlation of lattice parameters, the epitaxial growth relationship between the two composite films can be expressed as Pm-3m(100)∥P2₁/a(005), where Pm-3m represents the cubic lattice space group of CsPbBr₃, and P2₁/a represents the monoclinic lattice space group of C8-BTBT. With a reciprocal lattice basic vector of the nanocrystal with Miller index (100) being marked as G′₁₀₀, and a reciprocal lattice basic vector of the small molecule with Miller index (001) being marked as G₀₀₁, the relationship between the reciprocal lattice basic vectors of the two lattices is: G′₁₀₀/G₀₀₁=1/5.

The disclosed embodiments of the present disclosure are only used to illustrate the present disclosure. The preferred embodiments do not describe all the details and do not limit the disclosure to the specific embodiments described. Obviously, many modifications and changes can be made based on the content of this description. These embodiments selected and detailed in the present disclosure are to better illustrate the principle and practical application of the present disclosure, thus making those skilled in the art better understand and apply the present disclosure. The present disclosure is only limited by the claim set and all scope and equivalent thereof.

What is claimed is:

1. A method for preparing an organic semiconductor film, comprising at least the following steps:
preparing an inorganic nanocrystal with a shell structure, wherein the inorganic nanocrystal with the shell structure contains at least a metal ion and an anion;
performing synchronous ion exchange on the metal ion and the anion in the inorganic nanocrystal with the shell structure by using an another nanocrystal different from the inorganic nanocrystal with the shell structure to obtain a modified inorganic nanocrystal with a shell structure, wherein the another nanocrystal contains elements that are different from the anion and the metal ion in the inorganic nanocrystal with the shell structure;
dispersing the modified inorganic nanocrystal with the shell structure and an organic small molecule in an organic solvent to obtain a dispersion, wherein the organic small molecule has a conjugated molecular structure, and the organic small molecule and the modified inorganic nanocrystal satisfy a fractional matching relationship of lattice parameters; and
forming the dispersion into the organic semiconductor film.

2. The method of claim 1, wherein in the organic semiconductor film, the modified inorganic nanocrystal and the conjugated organic small molecule satisfy a fractional matching relationship of lattice parameters.

3. The method of claim 1, wherein the inorganic nanocrystal with the shell structure is prepared by an in-situ mercaptosiloxane passivation method, a ligand-exchange mercaptosiloxane passivation method, an in-situ aminosiloxane passivation method, or a ligand-exchange aminosiloxane passivation method.

4. The method of claim 1, wherein the dispersion is formed into the organic semiconductor film by inkjet printing, slot-die coating, or screen printing.

5. The method of claim 1, wherein a surface ratio and a crystalline morphology of the organic semiconductor film are controlled by a thickness of the organic semiconductor film and a volume fraction of the organic small molecule in the organic semiconductor film.

6. The method of claim 5, wherein the surface ratio of the organic semiconductor film is marked as SR, and 0.01<SR<1.

7. The method of claim 1, wherein the ion exchange method is performed by a process comprising:
adding the another nanocrystal containing an anion of a different element and a metal ion of a different element into the inorganic nanocrystal with the shell structure, and exchanging the anion and the metal ion in a lattice of the inorganic nanocrystal with the shell structure with those in a lattice of the another nanocrystal, during which the nanocrystal with the shell structure and the shell structure are relatively stable, and the another nanocrystal gradually dissociate until disappear.

8. The method of claim 1, wherein the another nanocrystal comprises an ion that does not undergo the ion exchange in a lattice of the inorganic nanocrystal with the shell structure.

9. The method of claim 1, wherein the obtained inorganic nanocrystal with the shell structure are doped in control by changing a type or a molar fraction of an anion and a metal ion that undergo the ion exchange in the another nanocrystal.

10. An organic semiconductor film, comprising at least:
a modified inorganic nanocrystal, which has a shell structure, and
an organic small molecule, which has a conjugated molecular structure,
wherein the organic small molecule and the modified inorganic nanocrystal satisfy a fractional matching relationship of lattice parameters.
